(19) United States
(12) Patent Application Publication
(10) Pub. No.: US 2009/0153252 A1
(43) Pub. Date: Jun. 18, 2009

(54) MULTI-BAND VOLTAGE CONTROLLED OSCILLATOR CONTROLLING MODULE, PHASE LOCKED LOOP UTILIZING WHICH AND RELATED METHOD THEREOF

(76) Inventors: Mei-Show Chen, Hsinchu City (TW); Wei-Che Chung, Yun-Lin County (TW); Yan-Hua Peng, Miaoli County (TW)

Correspondence Address: NORTH AMERICA INTELLECTUAL PROPERTY CORPORATION, P.O. BOX 506, MERRIFIELD, VA, 22116, US

(21) Appl. No.: 11/955,407

(22) Filed: Dec. 13, 2007

(51) Int. Cl. H03L 7/085; H03L 7/00

(52) U.S. Cl. 331/10; 331/18

(57) ABSTRACT

A multi-band VCO module includes a multi-band VCO and a controlling module. The multi-band VCO is for selecting a specific band from a plurality of bands according to a band selecting signal, and for outputting an oscillating signal according to a predetermined voltage and the specific band. The controlling module, coupled to the multi-band VCO, is for setting the band selecting signal according to a reference frequency of the reference signal and an oscillating frequency of the oscillating signal. A related method and a PLL circuit utilizing the multi-band VCO module are also disclosed.

### BACKGROUND OF THE INVENTION

1. Field of the Invention

The present invention relates to a voltage controlled oscillator module, a phase locked loop utilizing which and related method, and more particularly, to a multi-band voltage controlled oscillator module, a phase locked loop utilizing which and related method.

2. Description of the Prior Art

In electronic system, a phase locked loop (PLL) circuit is generally applied to synchronize signals. FIG. 1 is a diagram illustrating a prior art PLL circuit 100. As shown in FIG. 1, the PLL circuit 100 generally comprises a phase detector 101, a charge pump 103, a low-pass filter 105, a voltage controlled oscillator (VCO) 107, a frequency divider 109 and a frequency divider 111. The frequency divider 111 is utilized to frequency-divide an input signal IS with an input frequency Fᵢₙ to generate a reference signal RS with a reference frequency Fᵣ. The phase detector 101 compares the reference signal RS with the output signal OUS (with an output frequency Fₒᵤ) to output a phase detecting signal DS. The charge pump 103 determines whether to increase or decrease output charges according to the phase detecting signal DS. After the output charges of the charge pump 103 (or equivalent voltage) are processed by the low-pass filter 105, a filtered control voltage V_{CF} is generated. Then the VCO 107 determines an output oscillating signal OS with an oscillating frequency Fₒ according to a control charge V_{c}. The frequency divider 109 frequency-divides the oscillating frequency OS to generate the output signal OUS. The other detailed structure and operating methods are known by a person skilled in this art, therefore further description is omitted here.

The VCO requires a higher gain if it is to output a signal across a wide frequency range. However, the control voltage is easily influenced by factors such as the current in the charge pump or control path, and a VCO with a higher gain is more sensitive to the variation of the control voltage. Therefore, the VCO using a higher gain to output a signal across the wide frequency range will suffer output signal variation issues (such as jitter).

### SUMMARY OF THE INVENTION

It is therefore an objective of the present invention to provide a multi-band VCO module and a PLL circuit utilizing this module, to operate the multi-band VCO with a lower gain at an appropriate band to provide the required frequency.

According to one embodiment of the present invention, a multi-band voltage-controlled oscillator module comprises: a multi-band VCO, for selecting a specific band from a plurality of bands according to a band selecting signal, and for outputting an oscillating signal according to a predetermined voltage and the specific band; and a controlling module, coupled to the multi-band VCO, for setting the band selecting signal according to a reference frequency of the reference signal and an oscillating frequency of the oscillating signal.

A phase locked loop is provided according to one embodiment of the present invention, where the phase locked loop utilizes the above-mentioned multi-band VCO, and comprises: a phase detector, for generating a phase detecting signal according to a reference frequency of a reference signal and an oscillating frequency of an oscillating signal; a charge pump, coupled to the phase detector, for generating a control current according to the phase detecting signal; a low-pass filter, coupled to the charge pump, for generating a filtered controlling voltage according to the control current; a switch module, coupled to the low-pass filter and a predetermined reference voltage, for outputting the filtered controlling voltage in a first mode and for outputting the predetermined reference voltage in a second mode; a multi-band VCO, coupled to the switch module, for selecting a specific band from a plurality of bands according to a band selecting signal, and for outputting an oscillating signal according to an output voltage of the switch module and the specific band; and a controlling module, coupled to the reference signal and the multi-band VCO, for setting the band selecting signal in the second mode according to the reference frequency and the oscillating frequency.

According to one embodiment of the present invention, a method for controlling a multi-band VCO is disclosed. The multi-band VCO can support a plurality of bands, and an oscillating band of the multi-band VCO can approach a frequency corresponding to a target value by utilizing the method. The method comprises dividing the plurality of bands into groups of a plurality of layers, where each group of each layer comprises at least one band, respectively determining a band from the groups of all the layers to be most closely approaching the target value, and then selecting the oscillating band of the multi-band VCO from the searched bands.

According to the above-mentioned embodiments, the VCO with lower gain can output a required frequency, and the above system uses the “open loop” operation method to shorten the locking time.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a prior art PLL circuit.

FIG. 2 illustrates a PLL circuit using a multi-band VCO module according to one embodiment of the present invention.

FIG. 3 illustrates a fixing of the control voltage to find the preferred band shown in FIG. 2.

FIG. 4 illustrates a counter calculating the output frequency F_{OU2} shown in FIG. 2.

FIG. 5 illustrates the finding of the preferred band shown in FIG. 2, by utilizing various binary search methods.

### DETAILED DESCRIPTION

Certain terms are used throughout the following description and claims to refer to particular system components. As one skilled in the art will appreciate, manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” The terms “couple” and “couples” are intended to mean either an indirect or a direct electrical connection. Thus, if a first device couples to a second device, that connection may be through a direct electrical connection, or through an indirect electrical connection via other devices and connections.

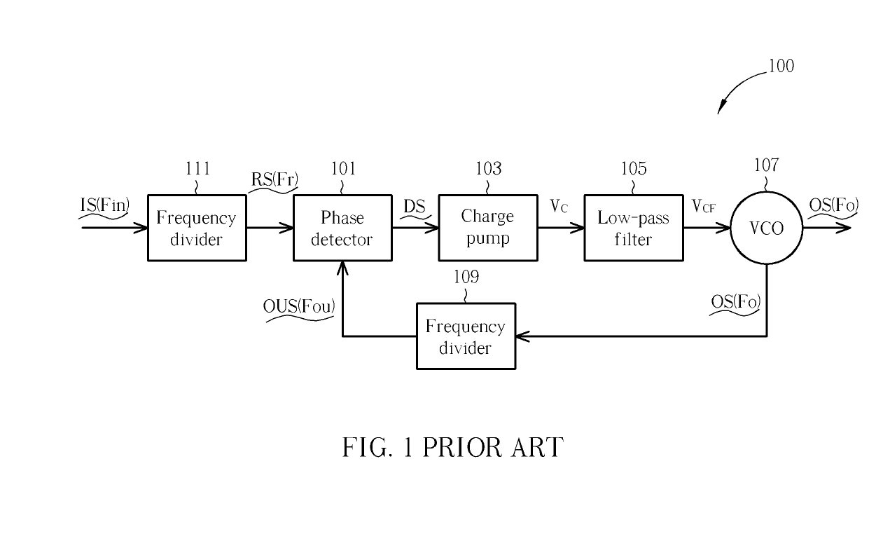

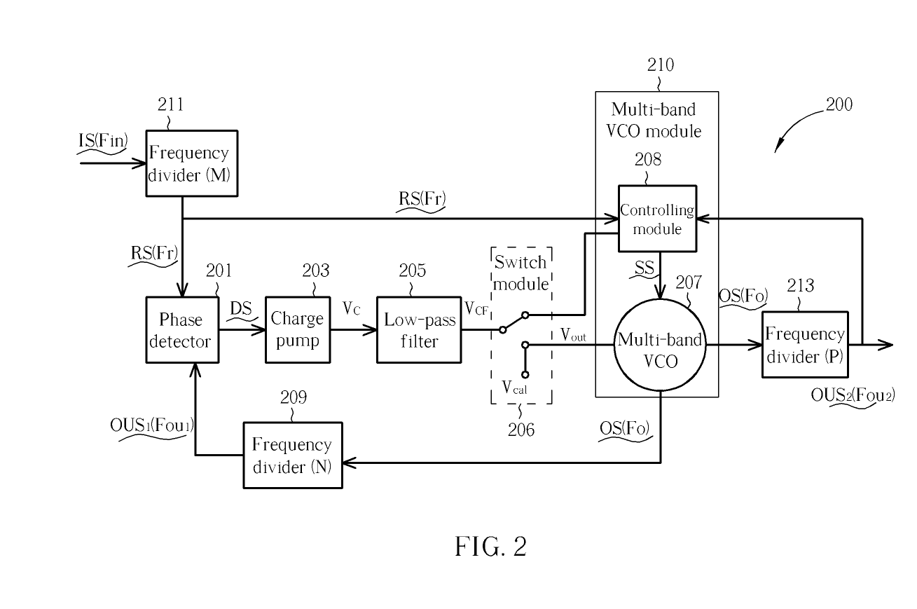

FIG. 2 illustrates a PLL circuit 200 using a multi-band VCO module according to one embodiment of the present invention. Compared with the PLL circuit 100 shown in FIG. 1, besides a phase detector 201, a charge pump 203, a low-pass filter 205, a frequency divider 209 with a frequency dividing ratio N, and a frequency divider 211 with a frequency dividing ratio M, the PLL circuit 200 further includes a switch module 206, a controlling module 208, and a frequency divider 213 with a frequency dividing ratio P. Furthermore, in the PLL circuit 200, the VCO is a multi-band VCO 207, and the controlling module 208 and the multi-band VCO 207 constitute a multi-band VCO module 210. Utilizing multi-band VCO module 210 in the PLL circuit is for illustrative purpose, without departing from the spirit of the present invention; the multi-band VCO module 210 can be utilized in other circuits.

The phase detector 201 generates a phase detecting signal DS according to a reference frequency Fᵣ of reference signal RS and an output frequency Fₒᵤₜ of an output signal OUS₁. The charge pump 203 generates a control charge V_{c} according to the phase detecting signal DS. The low-pass filter 205 generates a filtered control voltage V_{CF} according to the control charge V_{c}. The switch module 206 outputs the filtered control voltage V_{CF} in a first mode (when the controlling module is inactive), and outputs a predetermined reference voltage V_{cal} (which can be a constant value) in a second mode (the controlling module is active). The multi-band VCO 207 operates in a specific band of a plurality of bands according to a band selecting signal SS, and outputs the oscillating signal OS according to the output voltage of the specific band. The controlling module 208 sets the band selecting signal SS according to the reference frequency Fᵣ and an output frequency F_{OU2} in the second mode.

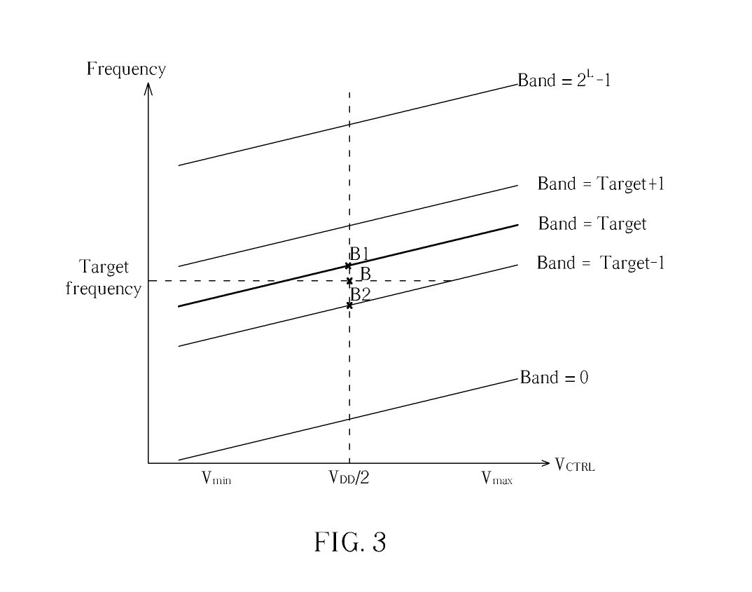

For simplicity, in the first mode, the controlling module 208 is inactive, the switch module 206 outputs the filtered control voltage VCF to the multi-band VCO 207, and the PLL circuit 200 is serving as a typical PLL circuit. And in the second mode, the switch module 206 maintains the control voltage of the multi-band VCO 207 at the predetermined reference voltage V_{cal}. In this embodiment, V_{DD}/2 and V_{DD} can be bias voltages of the PLL circuit 200. The controlling module 208 outputs the band selecting signal SS to the multi-band VCO 207 to select a better band from the bands provided by the multi-bands VCO 207. FIG. 3 illustrates fixing the control voltage to determine the preferred band shown in FIG. 2. As shown in FIG. 3, in the condition that the control voltage is fixed, the multi-band VCO 207 generates different frequencies corresponding to the different bands. Therefore, even if the control voltage is fixed, the multi-band VCO 207 can provide the required frequency by selecting the appropriate band. The band selecting method and other details are further described as follows.

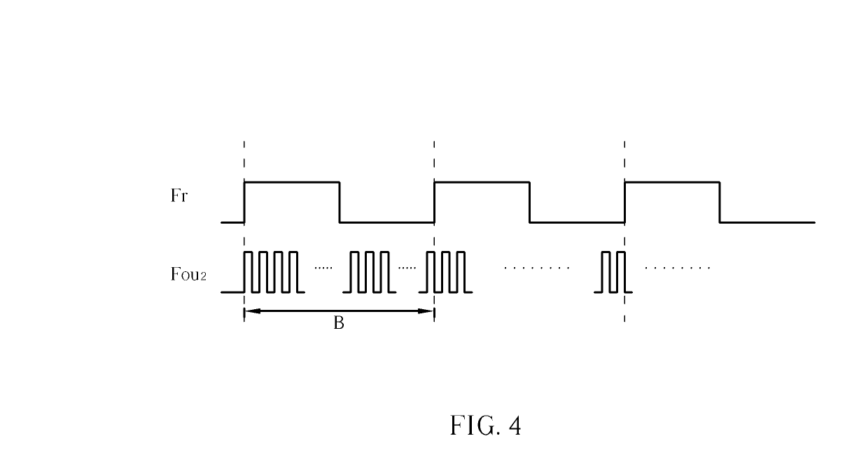

As mentioned above, the controlling module 208 determines the selecting signal according to the reference frequency Fᵣ and the output frequency F_{OU2}. Because the reference frequency Fᵣ is a known frequency and the output frequency F_{OU2} is an unknown frequency, however, the output frequency F_{OU2} needs to be calculated first. One method is by setting a counter in the controlling module 208, and using the counter to calculate the output frequency F_{OU2} according to the reference frequency Fᵣ. It is noted that this method is for exemplary purposes, and is not limiting the present invention. FIG. 4 illustrates the counter calculating the output frequency F_{OU2} shown in FIG. 2. As shown in FIG. 4, a counting value during a fixed period of the reference signal RS is obtained to determine the corresponding relationship between the output frequency F_{OU2} and the reference frequency Fᵣ. If the counting value is B during a period of the reference signal RS, the reference frequency Fᵣ is B times the reference output frequency F_{OU2}. And in this embodiment,

$${F}_{ou 2} = \frac{N}{P} \times {F}_{r} = B \times {F}_{r} ,$$

therefore, when the PLL circuit 200 locks, the number B should be equal to N/P. Therefore, it is known that the multi-band VCO 207 operates on the appropriate band by judging if the counting value B equals to N/P.

It is noted that, the above-mentioned frequency dividers 201, 209, and 213 are used to frequency-divide a high frequency into a low frequency for improving operations due to design requirements or device limits. However, it is not meant to limit the PLL circuit 200 to require a frequency divider. The frequency dividers 201, 209, and 213 can be removed from the PLL circuit 200 according to system requirements.

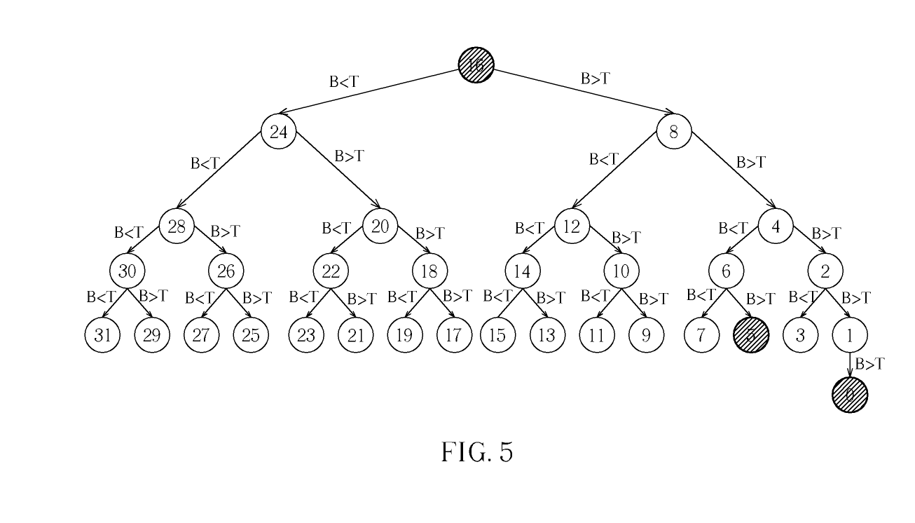

In the embodiment provided by the present invention, the controlling module 208 can use typical binary search method or a successive binary search provided by the present invention to determine the preferred band of the multi-band VCO 207. FIG. 5 illustrates determining the preferred band by utilizing various binary search methods shown in FIG. 2. In this embodiment, it is using a five-bit multi-band VCO and there are thirty-two bands, respectively numbered 0-31. In the embodiment shown in FIG. 5, first, the band numbered 16 (the middle band) is selected, and then the aforementioned counting value B is compared with a target value T (that is, N/P in this embodiment). When the value B is less than the value T, shift to a higher frequency by a shifting amount that is equal to one quarter of the total bands; in this embodiment, the band numbered 24 is selected. When the value B is greater than the value T, shift to a lower frequency by a shifting amount which equals one quarter of the total bands; in this embodiment, the band numbered 8 is selected. Then, in the band numbered 24, when the value B is less than the value T, shift to a higher frequency by an amount equal to one-eighth of the total bands (here, the band numbered 28 is selected). On the other hand, when the value B is greater than the value T, shift to a lower frequency by a shifting amount equal to one-eighth of the total bands (to the band numbered 20 in this embodiment). The above-mentioned similar steps will be continued until the counting value B approaches (or is equal to) the target value T. The present invention further discloses a successive binary search method for determining the preferred band of the multi-band VCO 207. The difference between the successive binary search method and the typical binary search method is that the typical binary search method stops searching when determining the same value (that is, when B is equal to T) or within a scope (that is, when B approaches T). The successive binary search method, however, searches all values and then determines the preferred band according to the searching result. One of the methods is to record the address of the best band after searching.

The operations of the binary search method and the successive binary search method are further described in FIG. 5. Assume for illustrative purposes that the corresponding frequency of the target value T is the same as the band numbered 5. When the binary search method is used, the searching sequence will be the band numbered 16, then 8, and then stop searching at the band numbered 4, because the corresponding frequency range of the band numbered 4 is close to the target value T. In the successive binary search method of the present invention, however, the bottom layer of the “binary” groups (that is, the layer of the bands numbered 1, 3, 5, 7, 9, . . . , 31 ) must be searched. Therefore, the best band numbered 5 (which is most close to the target value T) is selected according to the searching sequences band numbered 16, 8, 4, and 6, to achieve the preferred frequency.

Take another example, assuming that the corresponding frequency of the target value T is in accordance with the band numbered 12. When the typical binary search method is used, the searching sequence is the band numbered 16, band 8, and the searching stops at the band numbered 12. When the successive binary search method of the present invention is used, the searching sequence is bands numbered 16, 8, 12, 14, and 13. Then the preferred band (deviating least from the target value) numbered 12 is selected from the above five bands. Therefore, it is known that the successive binary search method of the present invention will search to the bottom layer of the binary groups, and the best band (deviating least from the target value) can indeed be selected among the searched bands; the successive binary search method will not stop searching in the middle layer and miss finding the actual most preferable band.

After generalizing the skill of the successive binary search method of the present invention, the spirit of the search method of the present invention can be described as follows. When using the controlling module 208 of the multi-band VCO module 210 to perform band selecting in the second mode, the present invention divides all the bands supported by the multi-band VCO into groups of a plurality of layers, and determines a band closest to the target value in the groups of all the layers. Finally, the present invention selects the best band (deviating least from the target value) among the searched bands. More specifically, according to the present invention, after selecting a band from a group, another band of the next group (going one layer further down) is selected according to the band. Applied in the embodiment shown in FIG. 5, the band numbered 16 is one group, the bands numbered 8 and 24 are groups of the second layer, and the bands numbered 4, 12, 20 and 28 are the groups of the third layer. Likewise, the bands numbered 2, 6, 10, 14, 18, 22, 26, and 30 are the groups of the fourth layer, and the bottom layer includes the bands numbered 1, 3, 5, 7, 9, 11, 13, 15, 17, 19, 21, 23, 25, 27, 29, and 31. As mentioned above, the improved binary search method of the present invention will search and determine a band in each layer, and determine the best band among theses searched bands. Arrows shown in FIG. 5 (e.g., the band numbered 8 points to the band numbered 4 and 12) represent, after selecting a band from a group, the possible bands in the next group to select, according to the band already selected. That is, in the groups of each layer, each band can correspond to a plurality of bands of the next group. After selecting a band from a group, another band of the next group can be determined according to the corresponding plurality of bands of the selected band. For example, in FIG. 5, the band numbered 16 corresponds to the bands numbered 8 and 24 of the group of the next layer, the band numbered 8 corresponds to the bands numbered 4 and 14 of the group of the next layer, and the band numbered 4 corresponds to the bands numbered 2 and 6 of the group of the next layer, and so on. Therefore, in the searching process, the successive binary search is performed according to this corresponding relationship.

When the PLL circuit 200 begins to operate, the PLL circuit 200 can operate in the second mode first to perform the above-mentioned successive binary search method to determine the best band. With this, the coarse adjustment is finished. Then the PLL circuit 200 switches to the first mode to perform fine-tuning on the phase detector 201, the charge pump 203, low-pass filter 205 and the multi-band VCO 207 of the PLL circuit, to lock the phase accurately. However, the applications of the present invention are not limited by this flow. For example, the present invention can switch from the first mode to the second mode again periodically (or under certain conditions) to perform coarse adjustment, and then switch back to the first mode.

In the present invention, the moving number of the bands in each step is not limited by this embodiment, and can be different according to the requirements. In addition, although in this embodiment the judgment criteria is set by comparing the counting value B and the target value T, if the controlling module 208 does not use the counter to count the output frequency F_{OU2} of the output signal OUS₂, the present invention can compare the reference frequency Fr and the output frequency FOU2 (or the oscillating frequency Fₒ, if there is no frequency divider). These alternatives are all in the scope of the present invention.

According to the above-mentioned embodiment, the VCO can output the required frequency with a low gain. And the above system uses a open loop operating method and therefore shortens the locking time.

Those skilled in the art will readily observe that numerous modifications and alterations of the device and method may be made while retaining the teachings of the invention.

What is claimed is:

1. A multi-band voltage-controlled oscillator (VCO) module, comprising:
a multi-band VCO, for selecting a specific band from a plurality of bands according to a band selecting signal, and for outputting an oscillating signal according to a predetermined voltage and the specific band; and
a controlling module, coupled to the multi-band VCO, for setting the band selecting signal according to a reference frequency of a reference signal and an oscillating frequency of the oscillating signal.

2. The multi-band VCO module of claim 1, wherein the controlling module counts the oscillating signal according to the reference signal, and adjusts the band selecting signal according to a counting result.

3. The multi-band VCO module of claim 2, wherein the controlling module compares the counting result with a predetermined value, and adjusts the band selecting signal by utilizing a successive binary search method.

4. The multi-band VCO module of claim 2, wherein the controlling module compares the counting result with a predetermined value, and after utilizing a typical binary search method to search all the bands, the controlling module adjusts the band selecting signal according to the searching result.

5. The multi-band VCO module of claim 1, wherein the controlling module compares the reference frequency with the oscillating frequency, and adjusts the band selecting signal by utilizing a successive binary search method.

6. The multi-band VCO module of claim 1, wherein the controlling module compares the reference frequency with the oscillating frequency, and after utilizing a typical binary search method to search all the bands, the controlling module adjusts the band selecting signal according to the searching result.

7. A phase locked loop, comprising:
a phase detector, for generating a phase detecting signal according to a reference frequency of a reference signal and an oscillating frequency of an oscillating signal;
a charge pump, coupled to the phase detector, for generating a control current according to the phase detecting signal;
a low-pass filter, coupled to the charge pump, for generating a filtered control voltage according to the control current;
a switch module, coupled to the low-pass filter and a predetermined reference voltage, for outputting the filtered control voltage in a first mode and for outputting the predetermined reference voltage in a second mode;
a multi-band VCO, coupled to the switch module, for selecting a specific band from a plurality of bands according to a band selecting signal, and for outputting an oscillating signal according to an output voltage of the switch module and the specific band; and
a controlling module, coupled to the reference signal and the multi-band VCO, for setting the band selecting signal in the second mode according to the reference frequency and the oscillating frequency.

8. The phase locked loop of claim 7, wherein the controlling module compares the reference frequency with the oscillating frequency, and adjusts the band selecting signal by utilizing a successive binary search method.

9. The phase locked loop of claim 7, wherein the controlling module compares the reference frequency and the oscillating frequency, and after utilizing a typical binary search method to search all the bands, the controlling module adjusts the band selecting signal according to a searching result.

10. The phase locked loop of claim 7, further comprising:
a frequency divider, coupled between the controlling module and the multi-band VCO, for frequency-dividing the oscillating signal to generate an output signal, and the controlling module sets the band selecting signal according to an output frequency of the output signal and the reference frequency.

11. The phase locked loop of claim 7, further comprising:
a frequency divider, coupled to the multi-band VCO and the phase detector, for frequency-dividing the oscillating signal to generate an output signal, and the phase detector generates the phase detecting signal according to the reference frequency of the reference signal and an output frequency of the output signal.

12. The phase locked loop of claim 7, further comprising:
a frequency divider, coupled to the multi-band VCO and the phase detector, for frequency-dividing the oscillating signal to generate an output signal, and the phase detector generates the phase detecting signal according to the reference frequency of the reference signal and an output frequency of the output signal.

13. The phase locked loop of claim 7, further comprising:
a frequency divider, coupled to the phase detector, for frequency-dividing an output signal to generate the reference signal.

14. The phase locked loop of claim 7, wherein the controlling module counts the oscillating signal according to the reference signal, and adjusts the band selecting signal according to a counting result.

15. The phase locked loop of claim 14, wherein the controlling module compares the counting result and a predetermined value, and adjusts the band selecting signal by utilizing successive binary search method.

16. The phase locked loop of claim 14, wherein the controlling module compares the counting result and a predetermined value, and after utilizing a typical binary search method to search all the bands, the controlling module adjusts the band selecting signal according to a searching result.

17. The phase locked loop of claim 14, further comprising:
a first frequency divider, having a first frequency dividing ratio and being coupled to the multi-band VCO and the phase detector, for frequency-dividing the oscillating signal to generate a first output signal; and
a second frequency divider, having a second frequency dividing ratio and being coupled to the multi-band VCO and the controlling module, for frequency-dividing the oscillating signal to generate a second output signal;
wherein when the phase locked loop locks, the ratio between the first frequency dividing ratio and the second frequency dividing ratio is equal to the counting value.

18. A method for controlling a multi-band voltage-controlled oscillator (VCO), wherein the multi-band VCO can support a plurality of bands, and an oscillating band of the multi-band VCO can approach a frequency corresponding to a target value by utilizing the method, the method comprises:
dividing the plurality of bands into groups of a plurality of layers, and each group of each layer comprises at least a band;
respectively searching a band most closely approaching the target value from the groups of all the layers according to the target value;
selecting the oscillating band of the multi-band VCO from the searched bands.

19. The method of claim 18, wherein when searching from the groups of all the layers, the method comprises:
after searching a band from a group, searching another band from a next group according to the searched band.

20. The method of claim 19, wherein when dividing the plurality of bands into groups of a plurality of layers, the band of the group corresponds to a plurality of bands of the next group; and when searching another band of the next group according to the searched band, searching another band from the plurality of bands corresponding to the searched band.
